(19) United States
(12) Patent Application Publication
(10) Pub. No.: US 2018/0166413 A1
(43) Pub. Date: Jun. 14, 2018

(54) ELECTRICALLY CONDUCTIVE BOND BETWEEN AT LEAST TWO ELECTRICAL COMPONENTS AT A CARRIER MOUNTED WITH ELECTRONIC AND/OR ELECTRICAL DEVICES, SAID BOND BEING FORMED BY A BOND WIRE

(71) Applicant: FRAUNHOFER-GESELLSCHAFT ZUR FOERDERUNG DER ANGEWANDTEN FORSCHUNG E.V., Muenchen (DE)

(72) Inventors: Christoph Bayer, Nuernberg (DE); Uwe Waltrich, Erlangen (DE); Andreas Schletz, Amberg (DE)

(73) Assignee: FRAUNHOFER-GESELLSCHAFT ZUR FOERDERUNG DER ANGEWANDTEN FORSCHUNG E.V., Muenchen (DE)

(21) Appl. No.: 15/837,280

(22) Filed: Dec. 11, 2017

(30) Foreign Application Priority Data
Dec. 9, 2016 (DE) 10 2016 224 631.3

(51) Int. Cl. H01L 23/00

(52) U.S. Cl. CPC H01L 24/48; H01L 24/45; H01L 2224/48137; H01L 2224/48091; H01L 2224/48097; H01L 2924/30107; H01L 2224/45139; H01L 2224/45147; H01L 2224/45124; H01L 2224/45565; H01L 2224/48998

(57) ABSTRACT

The invention relates to the electrically conductive bond between at least two electrical components and/or devices at a carrier mounted with electronic and/or electrical devices, said bond being formed by a bond wire. The bond wire is bonded in a force fitting, shape matching manner and/or with material continuity to the electrical components and/or devices and is shaped in an arcuate manner between the electrical components and/or devices at a spacing from the surface of the carrier and from electronic and/or electrical devices arranged there. The respective bond wire is bent a multiple of times with changing directions between the electrical components and/or devices such that tips or regions of individual arcs are arranged at different spacings from the surface of the carrier. At least one element formed from or by an electrically conductive material can, however, also be arranged between the surface of the carrier and the arcuate bond wire and the electrically conductive material is arranged at a spacing from the respective bond wire.

The invention relates to an electrically conductive bond between at least two electrical components at a carrier mounted with electronic and/or electrical devices, said bond being formed by a bond wire. They are in particular, for example, carriers for power electronics that can be operated with increased electrical voltage flanks and/or current flanks (increased switching speed). In this respect mutually electrically conductive components can in particular be semiconductor devices, passive devices, conductor tracks, terminals, copper pads or interconnect devices.

A carrier can also be an electrical terminal such as an electrically conductive bond or an electrical contact in/at a bond frame.

A bond wire can, however, also be understood as a solderable metallic conductor support in the form of a frame (leadframe), a strip-like electrical bonding element (ribbon bond or metal framework or flex bond, films). The term bond wire will be used exclusively in the following in the description and in the claims, with the said flexible electrically conductive bonds, in particular flexibly deformable electrically conductive bonds, and other equivalent flexible electrically conductive bonds, in particular flexibly deformable electrically conductive bonds, also being understood thereby.

These carriers are typically mounted with power semiconductor devices, transformers, inductive elements, capacitors, sensors and electrical measuring resistors. The electrical contacting of the individual elements to one another or to electrical components, in particular electrical contact points for external connectors, are typically formed by bond wires whose front ends are respectively electrically conductively bonded, e.g. with shape matching, force fitting and/or material continuity, to at least two electrical contact points. The bond can be established by soldering, welding, sintering or by an electrically conductive adhesive or by pressing. A bond wire (generally an electrically conductive bond) is in this respect as a rule formed in arc shape starting from the electrical contact points over and spaced apart from the surface of the carrier and elements fastened thereto.

Due to the customary arcuate shape, a single bond wire has an increased length and also a correspondingly high parasitic electrical inductance. This produces unwanted properties that in turn result in increased shutdown overvoltages, thermal power losses in power switches and in a limited increase speed of the electrical voltage and/or of the electrical current during switching procedures. Electrical vibration problems can also occur. The magnetic field of a parasitic inductance couples into adjacent circuit parts and results in problems in electromagnetic compatibility (EMC). In addition, adjacent electromagnetic fields can couple into the electrically conductive bonds in an interfering manner.

These disadvantages occur since an electromagnetic field is formed or is changed when electric current flows through the respective bond wire as a result of the respective electrical inductance. If a plurality of bond wires are arranged at correspondingly small intervals from one another at a carrier, it can additionally occur that one or more electromagnetic fields can deform and can even contact one another as a result of the force effect. This occurs in a particularly amplified manner when one or more bond wires have heated up due to the respective electric current flow or were heated up by the power device, which can in particular be the case with current peaks or power peaks.

This has previously been countered by a shortening of the bond wire length, whereby, however, the spacing of the arcuate bond wire from the surface is reduced. However, due to the reduced length and the associated higher mechanical stiffness, higher thermomechanical stresses can occur and a release or a breaking of the bond, preferably having material continuity, at electrical contact points or of the bond material itself can occur due to cyclical loads. Length changes as a result of thermal expansion can thus not be compensated sufficiently or can only be compensated to a much lesser degree, which at least negatively influences the achievable service life of the respective electrical contact point.

It is therefore the object of the invention to reduce the parasitic influence as a result of electrical inductance with electrically conductive bonds at carriers mounted with electrical and/or electronic components and formed by bond wires or to fix it to a desired value and also to achieve an elevated or at least constant stability on the operation of a carrier correspondingly mounted with electrical and/or electronic components.

This object is achieved in accordance with the invention by an electrically conductive bond having the features of claim 1. Advantageous embodiments of the invention can be realized using features designated in subordinate claims.

With the electrically conductive bond in accordance with the invention between at least two electrical components, in particular electrical contact connectors and/or devices at a carrier mounted with electronic and/or electrical devices, said bond is formed with a bond wire. The bond wire here is electrically conductively bonded in a force fitting, shape matching manner and/or with material continuity to the electrical components and/or devices and is shaped in an arcuate manner between the electrical components and/or devices at a spacing from the surface of the carrier and from electronic and/or electrical devices arranged there.

The electrically conductive bond can respectively be established by at least one bond wire between two components, between two devices, or between one component and one device.

In an alternative in accordance with the invention, the respective bond wire between the electrical components is bent a plurality of times in changing directions so that tips or regions of individual arcs are arranged at different spacings from the surface of the carrier. A change of direction of at least 90° should be observed at arcs.

In a further alternative that can be implemented on its own or together with the first alternative, at least one element formed from or by an electrically conductive material is arranged between the surface of the carrier and the arcuate bond wire and the electrically conductive material is arranged at a spacing from the respective bond wire.

The electrical components, in particular contact points, can be external electrical connectors or also contacts of a device with which the carrier is mounted.

A bond wire should be bent between the electrical contact points such that the surface effectively flowed around by electric current is smaller in comparison with a continuously bent bond wire and/or such that the electromagnetic field that is formed can store less energy in a surrounding electromagnetic field than an electromagnetic field that is generated by at least one standard bond wire shaped in arcuate form.

The possibility is also derived from this that a plurality of electrically conductive bonds having corresponding bond wires can be present at a carrier. Electrical current flows from and to a plurality of devices, also different devices, with which a carrier can be mounted, can be established with these electrically conductive bonds. In this respect, a plurality of bond wires having different orientations with respect to one another or also in parallel with one another can be fixed with material continuity and electrically conductively to electrical components or contact points.

An element formed from or by an electrically conductive material can simply be a wire, a cylinder, or an element geometrically shaped in a different manner that can simply be arranged there in the intermediate space between the arcuately curved wire and the surface of the carrier. It can be formed completely from an electrically conductive material or can be coated or covered at least in part by a coating of an electrically conductive material. A substrate of a ceramic or polymer material can thus e.g. correspondingly be coated with metal or covered by a metal film.

In the further alternative of the invention, the electrically conductive material of the element can be connected to potential.

It is also advantageous if a bond wire has a non-rotationally symmetrical cross-section. For this purpose, the middle longitudinal axis of the cross-sectional area of the bond wire aligned in parallel with the surface of the carrier can be longer than the middle longitudinal axis of the cross-sectional area of the bond wire aligned perpendicular to the surface of the carrier. The cross-sectional area of the bond wire can, for example, be rectangular, elliptical, or approximately semicircular or of part-circle shape. The stability of the bond wire formed in this manner can thereby be increased, in particular with respect to acting transverse forces, and the deformability in the formation of the multi-bent shape of the bond wire in a preferred axial direction can be improved.

It can be advantageous for a plurality of bond wires to be held in a fixed manner by at least one holding element in the region of at least one of the arcs of a bond wire such that a constant spacing from one another of bond wires arranged next to one another is observed and particularly advantageously such that the at least one holding element and the bond wires are electrically insulated from one another. Such a holding element can be formed by an electrically conductive material and can thus satisfy a dual function in that electromagnetic fields additionally formed around the bond wire or wires can be attenuated and thus the parasitic influence of the electrical inductance of the bond wire can be reduced by which an electric current flow takes place. A holding element can completely consist of an electrically conductive material and can only comprise an electrical insulation, for example in the form of a polymer or ceramic layer, in the contact region with the bond wires.

A holding element can be a discrete element and/or can be formed directly on the carrier, in particular by means of a print process. A holding element can have an electrically conductive surface that is preferably covered by an insulation layer. The electrical conductivity can be established by a metal or by an (intrinsically) electrically conductive plastic.

Corresponding moldings can be present at a holding element for fixing the bond wires and the bond wires can be led through or into them and can be held in them by shape matching. Groove-shaped recesses can in particular be formed at a front face of a holding element remote from the carrier surface and bond wires can engage into them and can be secured against lateral movements of the bond wires.

A bond wire used in the invention for an electrically conductive bond can have a non-constant cross-sectional area over its length and perforations or notches can be formed at it at predefinable intervals that form deformation aids and/or an element providing security against overloading. The configuration of the suitable arcuate shape between the electrical components can be facilitated by the function as deformation aids. A security against overloading can be configured in an analog manner to fuses known per se and can work accordingly since the cross-sectional area present in the regions for electrical conduction is reduced and the electrical resistance is increased there.

The arcuate formation of the respective bond wire, that is bent multiple times with changing directions so that tips or regions of individual arcs are arranged at different spacings from the surface of the carrier, can be achieved by a deformation after a formation of the bond having material continuity at the electrical components, for example by a defined pressing in using a correspondingly shaped plunger-like tool. In this respect, the perforations or notches explained above can be used to be able to form the desired arcuate shape. Perforations or notches can for this purpose be dimensioned in a suitable form and can be arranged at corresponding spacings from one another.

Tips can have a maximum or minimal spacing from the surface of the carrier at a correspondingly bent bond wire. Regions of a curved bond wire can be aligned in parallel with the surface of the carrier or, in regions not aligned in parallel with the surface of the carrier, at an angle thereto in the range from 5° to 20°. These regions can be bonded to further regions whose angles with respect to the carrier surface are larger than 20° or are connected to tips.

An arcuate shape suitable for the lowering of the parasitic electrical influences can, however, also be formed when being led past a shaping tool, in particular during or directly after the unwinding of the bond wire from a roll before the positioning and formation of the bond with force fitting, shape matching and/or material continuity to the electrical components.

A bond wire can preferably be formed from silver, copper, aluminum, from a plurality of components (e.g. copper core and aluminum skin) or from an alloy of at least one of these chemical elements and can preferably be provided with an electrically insulating coating.

The invention will be explained in more detail by way of example in the following. In this respect, the technical features shown in the individual Figures and described with respect thereto can be combined with one another independently of the respective individual example.

There are shown:

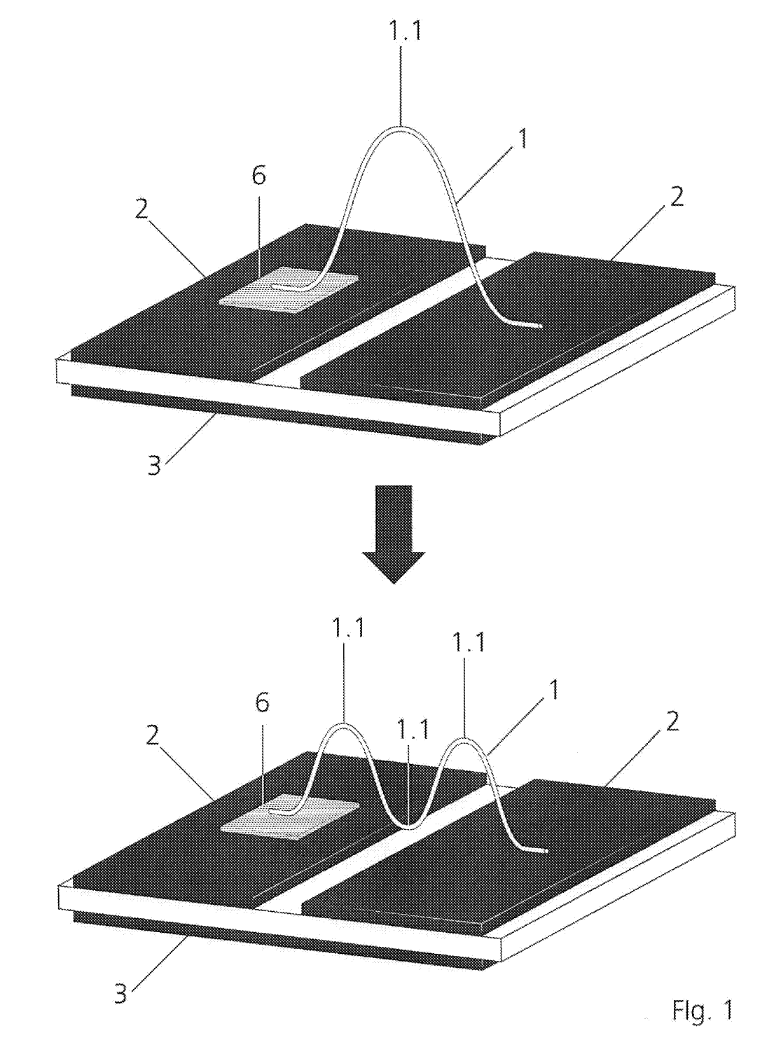

FIG. 1 in the upper illustration, a conventional electrically conductive bond; and in the lower illustration, an example of an electrically conductive bond in accordance with the invention with a bond wire in each case;

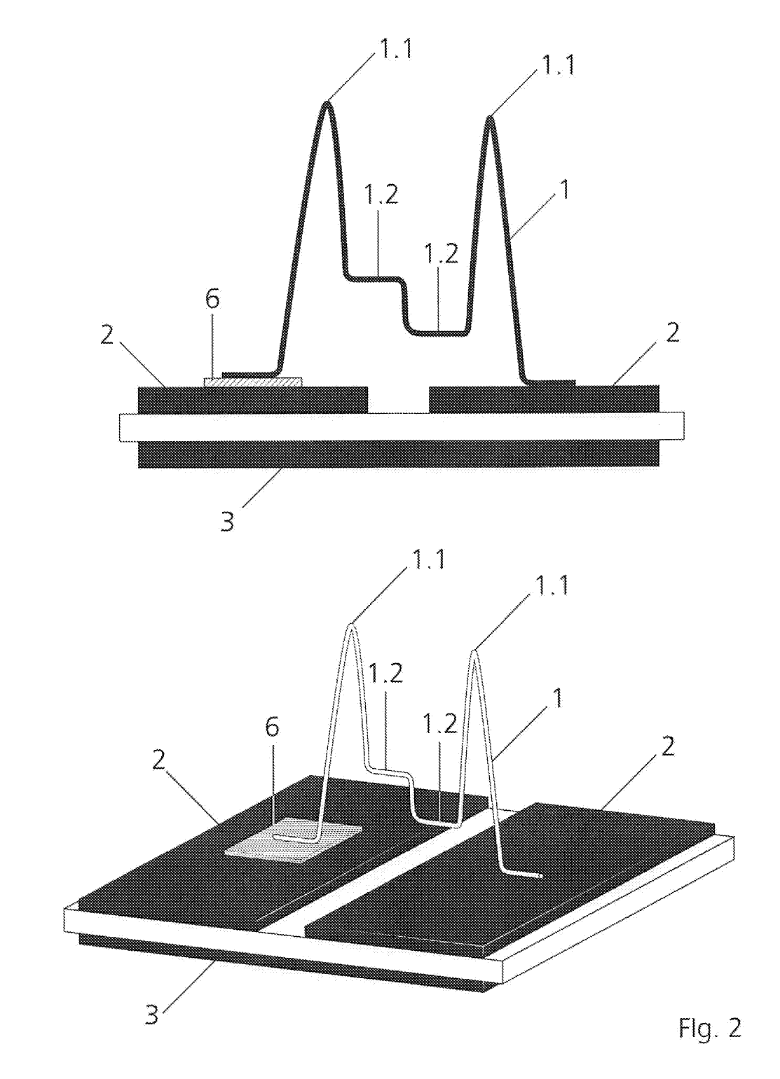

FIG. 2: a further example in accordance with the invention of bond wire forming an electrically conductive bond in a bent shape;

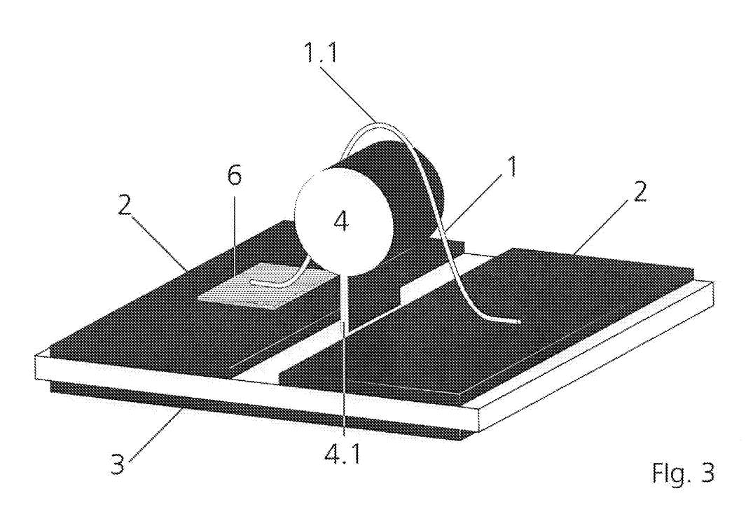

FIG. 3: an example of an electrically conductive bond in accordance with the invention with an element that is formed from or by an electrically conductive material and that is arranged between the bond wire forming the electrically conductive bond and the surface of a carrier; and

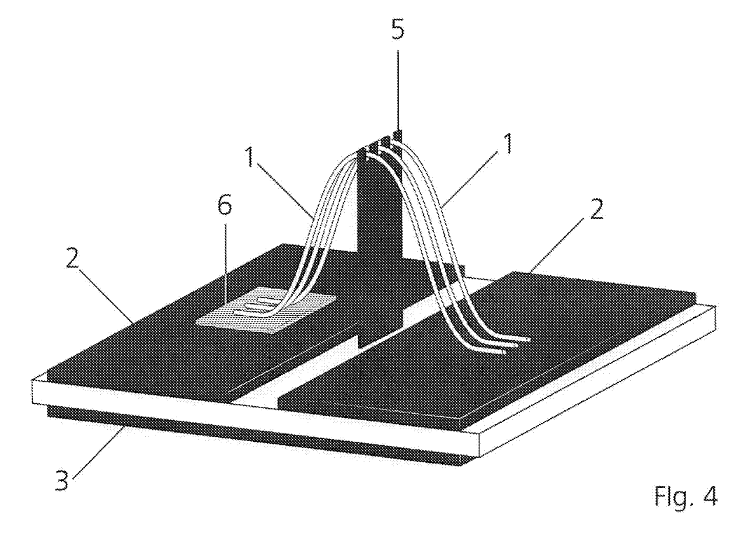

FIG. 4: a possibility of a fixing of a plurality of bond wires each forming an electrically conductive bond with a combined element that is formed by an electrically conductive material and that satisfies the function of a holding element.

An example in accordance with the prior art is shown in the upper illustration in FIG. 1. The bond wire 1 is here bonded with material continuity to the electrical contact points as electrical components 2 (or also to a device 6) and is shaped in arcuate form between the electrical contact points 2 at a spacing from the surface of the carrier 7 and from electronic or electrical devices arranged there. A further metalization 3 (or also another device with or without electrical conductivity) is located at the lower side. The arc formed by the bond wire only has a rounded tip 1.1. Considerable parasitic inductances occur as a result of the electrical inductance, which reduces the efficiency and increases the achievable switching times between changing operating states.

These disadvantages can be reduced in that the bond wire 1 is deformed multiple times in different directions so that tips 1.1 of individual arcs are arranged at different spacings from the surface of the carrier 7. The two outer tips 1.1 thus have a larger spacing from the carrier surface than the one tip 1.1 arranged therebetween.

The representation of the electrical and/or electronic devices present on the carrier 7 has been omitted with this and also with all the following representations of the different examples.

A further example in accordance with the invention of a bond wire 1 in arcuate form forming an electrically conductive bond is shown in FIG. 2.

The two-dimensional and three-dimensional representation shows the arrangement, shape, and bond of a bond wire 1 to two electrical contact points as electrical components 2 (or also to a device 6).

The two free front faces are used for the formation of the bond with material continuity to the electrical contact points 2 (or also to a device 6). The bond wire 1 is shaped therebetween with a plurality of changes of direction such that in this example two rounded outer tips 1.1 result that are bent in a direction facing away from the carrier surface. Two regions 1.2 are formed therebetween by further changes of direction at the bent bond wire 1, said regions each producing a different spacing from the carrier surface and naturally different spacings with respect to the bond wire regions by which the tips 1.1 are formed. A change of direction of approximately 90° with a radius at the direction transition avoiding a break of or damage to the respective bond wire 1 takes place at the regions 1.2.

The change of direction of the bend in the region of the tips 1.1 is just below 180°. A suitable transition radius should also be observed there.

More than the shown tips 1.1 or regions 1.2 can naturally be formed at a bond wire 1 in the examples in accordance with the invention of FIGS. 1 and 2. Regions 1.2 can also be present that each have the same spacings from the carrier surface when regions 1.2 or tips 1.1 are formed therebetween and/or therebeside whose spacings from the carrier surface are larger or smaller.

The spacings of tips 1.1 and/or regions 1.2 from the carrier surface can, however, also take account of devices 6 that are correspondingly arranged at the carrier surface since this kind of devices 6 frequently project beyond the carrier surface.

The desired target here is an extension of the bond wire 1 for a positive influencing of the service life of the electrical contact points, specifically the reduction of the thermomechanical strains. An increase of the parasitic electrical effects that otherwise accompanies this is, however, prevented by a special shape optimized to a low inductance and is reduced further than with standard shapes.

FIG. 3 shows an example of an electrically conductive bond in accordance with the invention with an element 4 that is formed from or by an electrically conductive material and that is arranged between the bond wire 1 forming the electrically conductive bond and the surface of a carrier 7. The bond wire 1 can also be bent a multiple of times in this embodiment and can have tips 1.1 and/or regions 1.2 having different spacings from the carrier surface, as is shown by way of example in FIGS. 1 and 2.

The element 4 is in this case a cylinder that is arranged between the carrier surface and the tip 1.1 of the bond wire 1 beneath the bond wire 1. The element 4 is in this example formed from a material that has paramagnetic, diamagnetic or also ferromagnetic properties and is provided with an electrically conductive surface layer or is covered by a film that e.g. comprises aluminum. The element 4 is electrically insulated from the carrier surface by the base 4.1. At least that region of the element 4 that is formed by the electrically conductive aluminum has a spacing from the bond wire 1 and is either loaded at a predefinable electrical potential, is connected to ground potential, or the region is acted on by a changing electrical potential or is also electrically conductively connected to a potential adopted in the circuit.

FIG. 4 shows a possibility of fixing of a plurality of bond wires 1 each forming an electrically conductive bond with a combined element that is formed by an electrically conductive material and that satisfies the function of a holding element 5.

The three bond wires 1 shown here are in this respect aligned almost in parallel with one another, arranged at spacings from one another, and bent approximately the same. They can be connected at their front faces with material continuity to a plurality of electrical contact points electrically insulated from one another as electrical components 2 (or also a device 6).

The holding element 5 is connected to the carrier 7, which can be achieved by material continuity (adhesive bonding, soldering, welding) and/or by shape matching by means of a suitable plug-in connection.

Groove-shaped recesses are formed at the end face remote from the carrier surface for a shape-matched reception of the bond wires 1 and the bent bond wires 1 are guided therethrough in the region of their tips 1.1. The bond wires 1 are fixed in the groove-shaped recesses in this manner and the bond wires 1 can thus not be moved toward one another and away from one another. The possible force effect of adjacent electromagnetic fields formed around bond wires 1 and having an attractive or repelling effect can thus be compensated.

In the simplest case, a holding element 5 can be completely formed from an electrically insulating material (ceramic, polymer). There is, however, also the possibility of forming a holding element 5 from or by an electrically conductive material, except for the regions that can come into touching contact with a bond wire 1. The regions that come into touching contact with a bond wire 1 can be formed by or provided with an electrical insulation. The front face having the groove-shaped recesses can thus, for example, be coated with an electrically insulating layer.

Only regions of a holding element 5 that cannot come into touching contact with bond wires 1 can, however, also be coated by or covered with a layer or film of an electrically conductive material.

In a non-shown form, the end face of a holding element 5 can also be formed as not in a straight line so that groove-like recesses having different spacings from the carrier surface can fix bond wires 1 having different lengths and different shapes by a holding element 5. Bond wires 1 that are bent multiple times in different directions and have tips 1.1 and/or regions 1.2 that are formed in an analog manner to FIGS. 1 and 2 can therefore also be fixed by a correspondingly designed holding element 5.

The parallelism of the bond wires is also not absolutely necessary. Curved holding element 5 whose end surface remote from the carrier surface can be formed curved in part-circle shape can also be used.

1. An electrically conductive bond between at least two electrical components (2) and/or devices (6) at a carrier mounted with electronic and/or electrical devices, said electrically conductive bond being formed with a bond wire (1), wherein the bond wire (1) is bonded with a force fit, shape matching and/or material continuity to the electrical components (2) and/or devices (6) and is shaped in arcuate form between the electrical components (2) and/or devices (6) at a spacing from the surface of the carrier (7) and electronic and/or electrical devices (6) arranged there, characterized in that
the respective bond wire (1) is bent a multiple of times with changing directions between the electrical components (2) and/or devices (6) such that tips (1.1) or regions (1.2) of individual arcs are arranged at different spacings from the surface of the carrier (7);
and/or in that at least one element (4) formed from or by an electrically conductive material is arranged between the surface of the carrier (7) and the arcuate bond wire (1) and the electrically conductive material is arranged at a spacing from the respective bond wire (1).

2. A bond in accordance with claim 1, characterized in that the electrically conductive material of the element (4) is connected to a predefinable electrical potential or ground potential.

3. A bond in accordance with claim 1, characterized in that the bond wire (1) has a non-rotationally symmetrical cross-section.

4. A bond in accordance with claim 1, characterized in that the middle longitudinal axis of the cross-sectional area of the bond wire (1) aligned in parallel with the surface of the carrier (7) is longer than the middle longitudinal axis of the cross-sectional area of the bond wire (1) aligned perpendicular to the surface of the carrier (7).

5. A bond in accordance with claim 3, characterized in that the cross-sectional area of the bond wire (1) is rectangular, elliptical or approximately semicircular or of part-circle shape.

6. A bond in accordance with claim 1, characterized in that a plurality of bond wires (1) are held fixed by at least one holding element (5) in the region of at least one of the arcs of a bond wire such that a constant spacing of the bond wires (1) from one another is observed and the at least one holding element (5) and the bond wires (1) are electrically insulated from one another.

7. A bond in accordance with claim 6, characterized in that the at least one holding element (5) is formed by an electrically conductive material that is a discrete element and/or is formed directly on the carrier (7), in particular by means of a print process.

8. A bond in accordance with claim 7, characterized in that the holding element (5) has an electrically conductive surface that is preferably covered by an insulation layer. The electrical conductivity can be established by a metal or by an (intrinsically) electrically conductive plastic.

9. A bond in accordance with claim 1, characterized in that a bond wire (1) does not have a constant cross-sectional area over its length; and in that perforations or notches are formed at predefinable spacings that form deformation aids and/or an element providing security against overload.

10. A bond in accordance with claim 1, characterized in that a bond wire (1) is formed from silver, copper, aluminum, a plurality of metals or an alloy of at least one of these chemical elements and is preferably provided with an electrically insulating coating.

11. A bond in accordance with claim 1, characterized in that a bond wire (1) is bent between the electrical contact points (2) such that the current circuit surface effectively flowed through by the electric current is smaller in comparison with a continuously curved bond wire (1); or
in that an electromagnetic field is generated that has an opposite field direction than an electromagnetic field that is generated by at least one further bond wire (1) arranged next to the respective bond wire (1);
and/or in that forming electromagnetic fields can store less energy in a surrounding electromagnetic field than an electromagnetic field that is generated by at least one standard bond wire (1) shaped in arcuate form.
